(19) United States
(12) Patent Application Publication
(10) Pub. No.: US 2011/0057259 A1
(43) Pub. Date: Mar. 10, 2011

(54) METHOD FOR FORMING A THICK BOTTOM OXIDE (TBO) IN A TRENCH MOSFET

(76) Inventor: Tiesheng Li, San Jose, CA (US)

(21) Appl. No.: 12/554,326

(22) Filed: Sep. 4, 2009

(51) Int. Cl. H01L 29/78; H01L 21/28; H01L 21/336

(52) U.S. Cl. 257/333; 438/589; 438/270; 257/E29.262; 257/E21.41; 257/E21.158

(57) ABSTRACT

A method for forming a thick bottom oxide in the bottom of a trench used in a vertical MOSFET. Initially, an n-type substrate has an n-type epitaxial layer grown thereon. A top portion of the n-type epitaxial layer is implanted with p-type dopants to provide a p-layer. A trench is then etched into the p- and n-type epitaxial layer. A high density plasma chemical vapor deposition (HDPCVD) process is used to either partially or fully fill the trench. Any oxide on the top surface of the p-layer is then removed, such as by using a chemical mechanical polishing step. Then, an isotropic etching step, such as a wet etch, is used to remove the silicon dioxide from the trench, while leaving a thick bottom oxide at the bottom of the trench. The HDPCVD process utilizes minimal thermal budget to form the thick bottom oxide.

### TECHNICAL FIELD

The present invention relates to vertical trench MOSFETs, and more particularly, to a method of forming a thick bottom oxide in the trench of the MOSFET.

### BACKGROUND

The vertical trench gated power MOSFET has rapidly displaced various forms of power MOSFETs due to performance and size improvements. For example, the vertical trench MOSFET can provide high density and current capability while having low on-state resistance and good off-state voltage blocking performance. In a trench MOSFET, current flows vertically through the substrate. A gate is formed within the trench of the substrate. The gate is typically formed from embedded polysilicon.

It is also known that a thick bottom oxide is desirable at the bottom of the trench in order to improve the gate breakdown voltage. Also, having a thick bottom oxide lowers the gate to drain capacitance. Examples of prior art methods of forming a thick bottom oxide in a vertical trench MOSFET can be seen in U.S. Patent Publication No. 2007/0202650 entitled “Low Voltage Power MOSFET Device and Process for Its Manufacturer.” In that disclosure, a silicon dioxide layer is grown on the exposed silicon at the bottom of the trench. This growth is typically performed using thermal oxidation. However, a drawback of such a technique is that thermal oxidation increases the thermal budget required in the process.

Another method of forming the thick bottom oxide is disclosed in U.S. Patent Publication No. 2005/0236665 entitled “Trench MIS Device Having Implanted Drain/Drift Region and Thick Bottom Oxide and Process for Manufacturing the Same.” As disclosed in that publication, the thick bottom oxide layer is formed on the bottom of the trench while sidewall spacers are still in place. In that disclosure, the thick bottom oxide can be formed by thermal growth or by conventional chemical vapor deposition. However, this method again increases the thermal budget, and/or is unsuitable for high aspect ratio trench MOSFETs.

### BRIEF DESCRIPTION OF THE DRAWINGS

FIGS. 1-7 are cross-sectional views of a semiconductor substrate showing the process of forming a thick bottom oxide for use in a trench MOSFET in accordance with one embodiment of the present invention.

FIG. 8 illustrates formation of the MOSFET gate and source after the thick bottom oxide trench has been formed.

FIGS. 9-13 illustrate formation of a trench in a substrate in accordance with an alternative aspect of the present invention.

### DETAILED DESCRIPTION

A method for forming a thick bottom oxide in the bottom of a trench used in a vertical MOSFET. Initially, an n-type substrate has an n-type epitaxial layer grown thereon. A top portion of the n-type epitaxial layer is implanted with p-type dopants to provide a p-layer. A trench is then etched into the p- and n-type epitaxial layer. A high density plasma chemical vapor deposition (HDPCVD) process is used to either partially or fully fill the trench. Any oxide on the top surface of the p-layer is then removed, such as by using a chemical mechanical polishing step. Then, an isotropic etching step, such as a wet etch, is used to remove the silicon dioxide from the trench, while leaving a thick bottom oxide at the bottom of the trench. The HDPCVD process utilizes minimal thermal budget to form the thick bottom oxide. Next, a thin gate oxide is formed on the side walls of the trench using a thermal oxidation step. After the gate oxide layer is formed, conventional steps are used to finish the vertical MOSFET, including formation of a polysilicon gate within the trench and n+ doping on the regions adjacent the trench to form the source regions of the MOSFET.

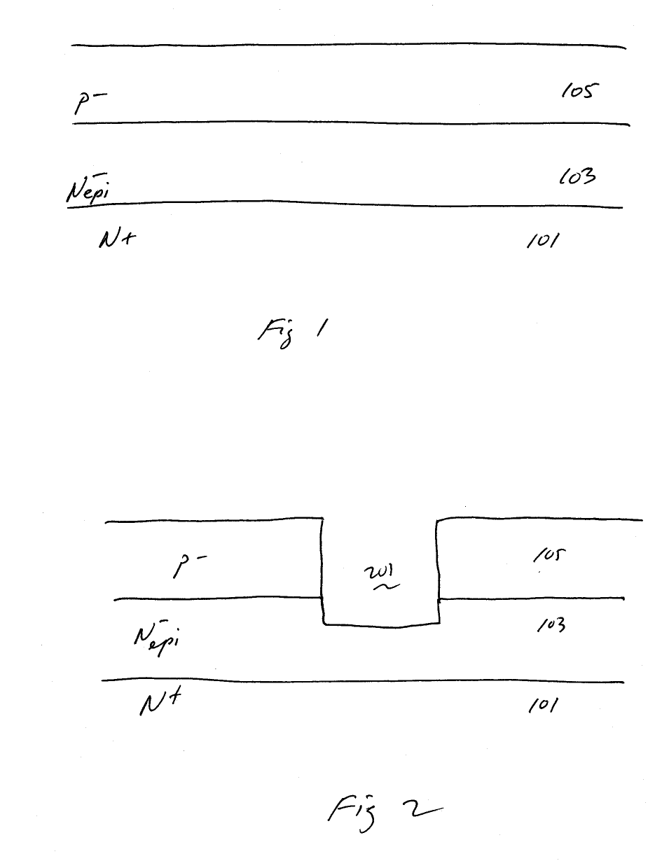

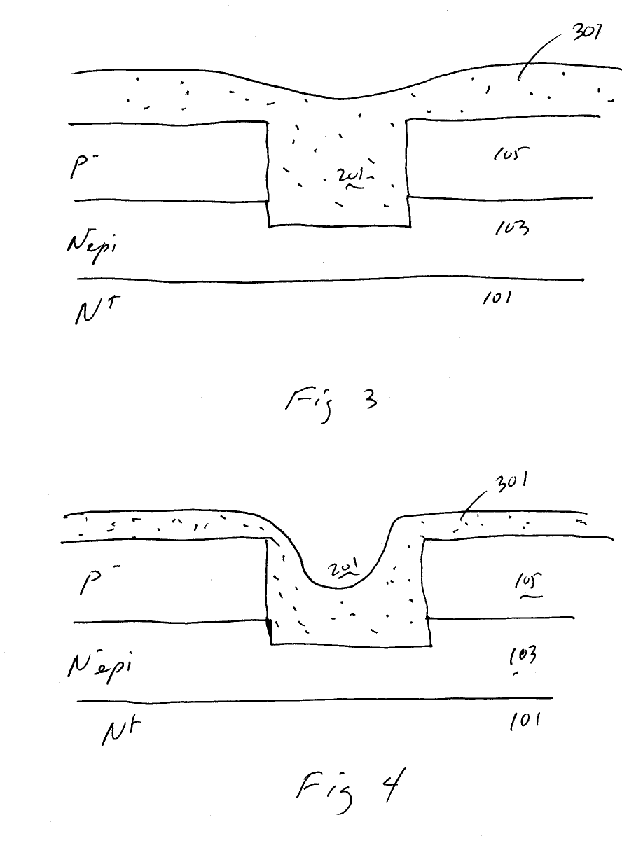

Specifically, turning to FIG. 1, an n+ substrate 101 is provided. Using conventional means, an n− epitaxial 103 is grown atop the n+ substrate 101. Next, using implantation techniques, a p-layer 105 is formed in the n− epitaxial layer. The p-layer 105 is also referred to as the “body” or the “base”. After this basic structure has been formed as shown in FIG. 1, a trench is etched into this structure as shown in FIG. 2. In one embodiment, the etching of the trench is performed using photolithography masking techniques and using an anisotropic etching to form the trench 201. It should be noted that while only a single trench is shown in FIG. 2, in practical application, there will be multiple trenches 201 formed in the substrate at the same time to generate trenches for a multitude of MOSFET devices. However, in the interest of clarity, only a single trench 201 is shown. Also, in one embodiment, the depth of the trench 201 extends down into the n-type epitaxial layer, but not the n+ substrate 101. The term “substrate” as used herein also refers to the combination of the p-type layer 105, the n-type epitaxial 103, and the n-type substrate 101.

Additionally, although the substrate is an n+ substrate and the epitaxial layer is n-type with a p-type implanted layer, the types of the semiconductor layers can be reversed, thus forming a pnp type transistor instead of an npn type transistor. Finally, it should be noted that, for clarity, the particular aspect ratio of the trench 201 is depicted as being relatively low in the Figures compared to typical applications. In other words, the ratio of the depth of the trench 201 to the width of the trench 201 is shown in the Figures to be on the order of 1 to 1.5. However, in most applications, the aspect ratio will be higher than that, and typically greater than 2.

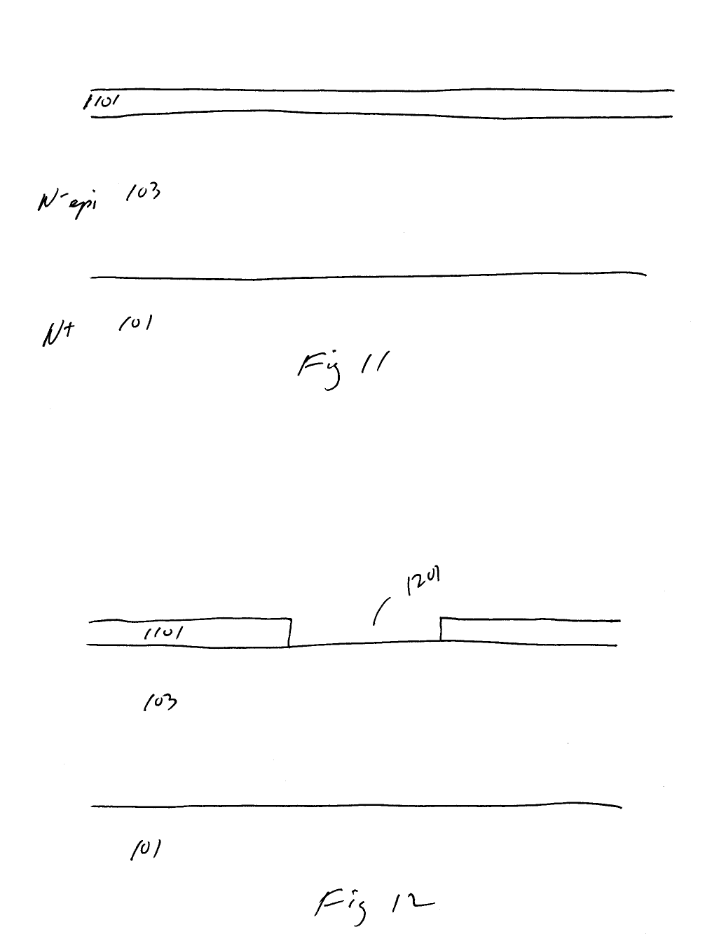

In an alternative embodiment, the trench 201 is formed prior to formation of the p-type layer 105. Thus, the trench 201 is formed after the n-type epitaxial layer 103 is formed on the substrate. This can be seen best in FIG. 9 where an n-type epitaxial layer 103 is grown atop the substrate 101. The p-layer is not formed using an implant until after the gate is formed within the trench 201. Thus, turning to FIG. 10, a trench 201 is formed using conventional etching techniques.

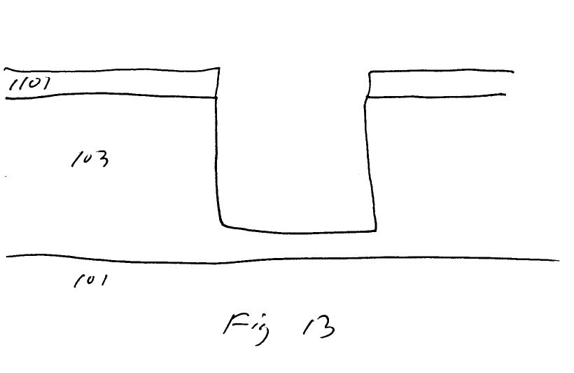

For example, the trench 201 may be etched using either a hard mask or a soft mask. In one embodiment, the hard mask is formed prior to the trench etching. As seen in FIG. 11, a hard mask 1101, such as an oxide/nitride/oxide (ONO) stack, may be used. Alternatively, a single silicon dioxide layer may be used as the hard mask. Turning to FIG. 12, once the hard mask 1101 is deposited, it is masked and etched to leave an opening 1201 that will be used to mask the etching of trench 201. Additionally, the hard mask 1101 has the advantage of being a hard stop layer for the subsequent chemical mechanical polishing process described below. The completed trench 201 is shown in FIG. 13 with the ONO hard mask layer 1101.

After the trench has been formed, next, turning to FIG. 3, using a high density plasma chemical vapor deposition process (HDPCVD), a silicon dioxide layer is deposited over the substrate and epitaxial layer, thereby filling the trench 201. The silicon dioxide layer 301 is used advantageously for high aspect ratio trenches 201. Further, the use of the HDPCVD process results in a thicker oxide thickness at the bottom relative to the sidewalls. Additionally, the HDPCVD process has a very low thermal budget impact. This is because typically the HDPCVD process is performed at a temperature of less than 300° C., by flowing silane and oxygen into the reaction chamber.

The HDPCVD process is a combination of deposition and sputtering. By controlling the deposition to sputter ratio, various aspect ratios of the trench 201 can be easily filled. In general, and without being limiting, the higher the aspect ratio of the trench 201, the higher the deposition to sputter ratio required in the HDPCVD process. In one embodiment, the deposition to sputter (D/S) ratio is greater than 4.

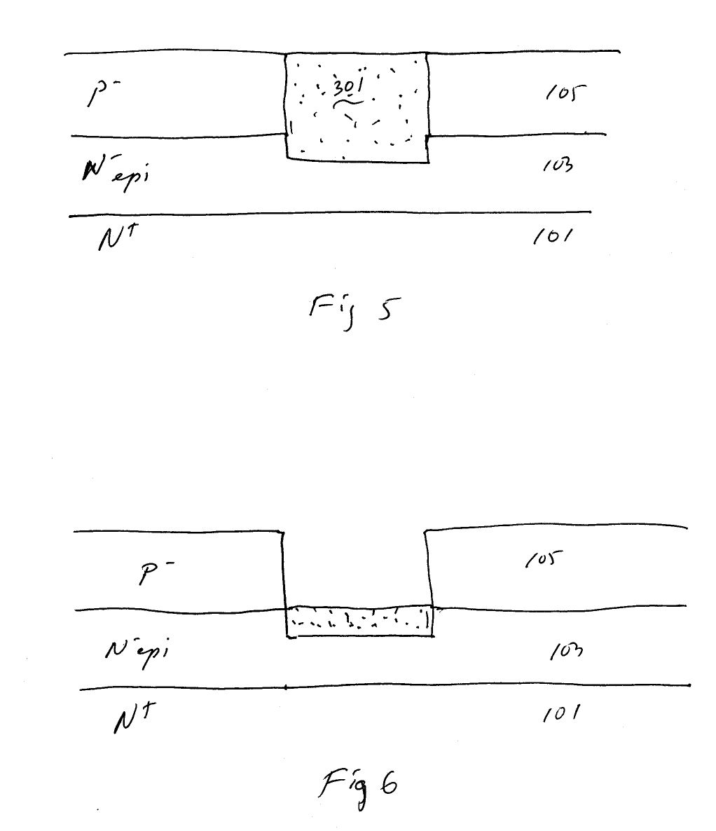

Once the oxide layer 301 has been formed into the trench 201, further processing steps are then required. At this point, it should be noted that the trench 201 need not be completely filled by the oxide 301. Indeed, as shown in FIG. 4, the trench 201 may be only partially filled by the oxide 301. This is a matter of design choice based upon the quality of the HDPCVD process used, and the aspect ratio of the trench 201.

In any event, the oxide 301 that lies outside of the trench 201 should be removed. This can be done using, for example, a chemical mechanical polishing step that stops on the top surface of the p-layer. Alternatively, an isotropic wet etch or a anisotropic dry etch may be used to remove portions of oxide 301 outside of the trench 201. However, this may result in portions of the oxide within the trench 201 being removed as well. As will be seen below, this may also be advantageous if the oxide 301 on the sidewalls f the trench are fully or partially removed in this step.

If a chemical mechanical polishing step is used, the remaining oxide 301 within the trench 201 is thus an oxide plug. Again, depending upon the quality of the CMP process, it may be difficult to stop the CMP process at the p-silicon surface. Thus, in an alternative embodiment, as noted above, prior to the deposition of the oxide 301, a thin silicon nitride layer, a silicon oxide layer, or an ONO layer may be deposited over the p-layer 105. This will provide a hard stop to the CMP process and advantageously provides greater control during the CMP process. While what has been described as a CMP process taking place after the oxide deposition, in an alternative embodiment, the CMP process may take place after the polysilicon gate plug is formed within the trench.

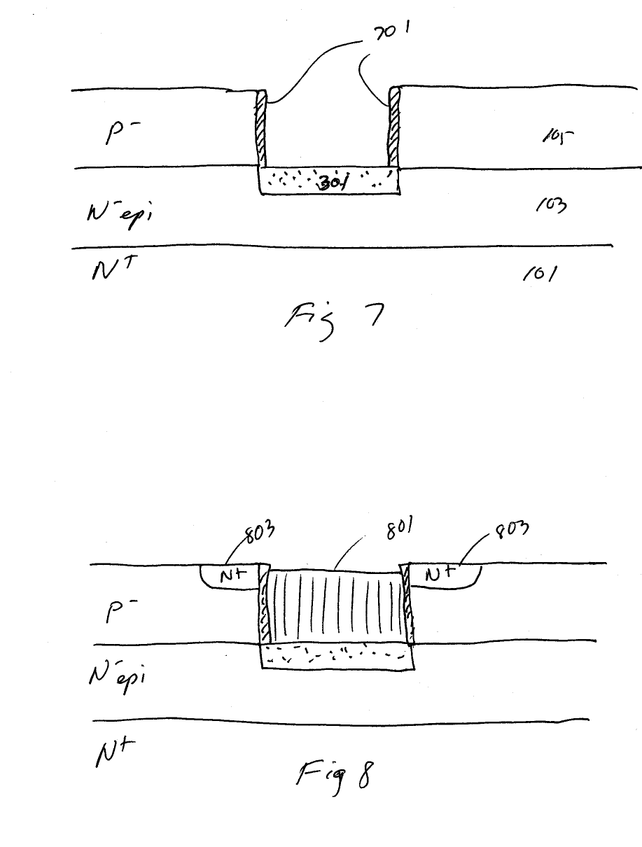

Next, turning to FIG. 6, the oxide plug 301 is etched back to leave a thick bottom oxide layer at the bottom of the trench 201. In one embodiment, an isotropic etch is used to remove the oxide. The isotropic edge is advantageous for removing the oxide from the side walls of the trench 201. It can be appreciated that various isotropic etching techniques, dry or wet, may be utilized to remove the portion of the oxide 301. In one actual embodiment, to illustrate the various dimensions utilized, the depth of the trench 201 is on the order of 1.34 microns, the width of the trench 201 is on the order of 0.35 microns, and the thickness of the oxide at the bottom of the trench is on the order of 0.3 microns. Thus, as can be seen, the aspect ratio of the trench is approximately 3 to 1.

Next, turning to FIG. 7, the gate oxide of the MOSFET is formed on the side walls of the trench 201. The gate oxide should be of high quality and thus the gate oxide 701 is, in one embodiment, formed using thermal oxidation of the silicon. Note that if thermal oxidation is used to form a side wall gate oxide 701, an optional further CMP step may be utilized to remove the oxide formed on top of the p-layer. Alternatively, the oxide may be left atop the p-layer and formation of the n+ source regions may be done using implantation through the thin gate oxide layer.

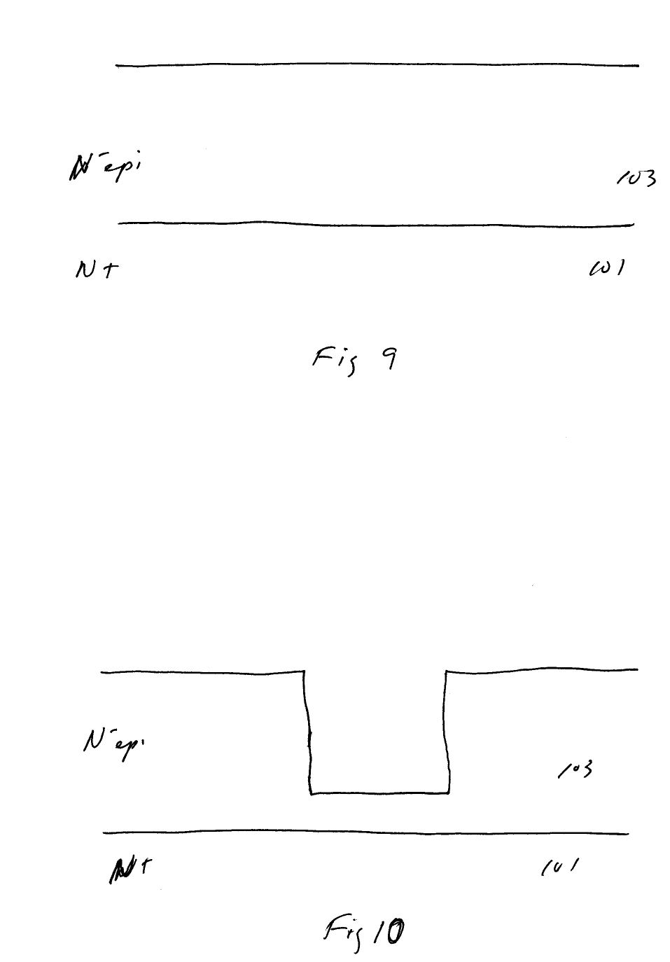

The remaining steps to form the MOSFET are conventional trench MOSFET processes and will not be detailed here in order to avoid obscuring the invention. However, briefly, a polysilicon plug 801 is formed in the trench 201 as seen in FIG. 8. Additionally, source regions 803 are formed adjacent the polysilicon gate 801. This is also seen in FIG. 8.

Note that in the alternative embodiment described in FIGS. 9-13, the p-layer can be formed after the polysilicon plug 801 is formed. This is done by the implantation of p-type dopants.

From the foregoing, it will be appreciated that specific embodiments of the invention have been described herein for purposes of illustration, but that various modifications may be made without deviating from the spirit and scope of the invention. Accordingly, the invention is not limited except as by the appended claims.

1. A method for forming a thick bottom oxide for a trench MOSFET comprising:
forming a trench in a semiconductor substrate;
using a high density plasma chemical vapor deposition (HDPCVD) process to form silicon dioxide at least partially into the trench and on a top surface of said substrate;
removing the silicon dioxide from the top surface of the substrate; and
removing the silicon dioxide from the sidewalls of the trench.

2. The method of claim 1 wherein the removing the silicon dioxide from the sidewalls of the trench is performed during the removing the silicon dioxide form the top surface of the substrate.

3. The method of claim 1 wherein the removing of the silicon dioxide from the top surface of the substrate is by a chemical mechanical polishing process.

4. The method of claim 1 wherein the silicon substrate is an n-type epitaxial layer formed atop of an n-type substrate, and further wherein said n-type epitaxial layer has a p-type implant formed therein.

5. The method of claim 1 wherein the silicon dioxide fills the trench.

6. The method of claim 3 further wherein a nitride layer is formed prior to the HDPCVD process and the nitride layer is used as a stop layer for the chemical mechanical polishing.

7. The method of claim 1 further including forming a gate oxide on the sidewalls of the trench by using a thermal oxidation process.

8. The method of claim 1 wherein the HDPCVD process occurs at a temperature of under 300 degrees Celsius.

9. The method of claim 1 wherein the process of removing the silicon dioxide on the sidewalls of the trench is by an isotropic wet etch process.

10. A MOSFET trench with a thick bottom oxide comprising:
a trench in a semiconductor substrate; and
a thick bottom oxide formed in the bottom of the trench, the thick bottom oxided formed by:
using a high density plasma chemical vapor deposition (HDPCVD) process to form silicon dioxide at least partially into the trench and on a top surface of said substrate;
removing the silicon dioxide from the top surface of the substrate; and
removing the silicon dioxide from the sidewalls of the trench.

11. The MOSFET trench of claim 10 wherein the removing the silicon dioxide from the sidewalls of the trench is performed during the removing the silicon dioxide form the top surface of the substrate.

12. The MOSFET trench of claim 10 wherein the removing of the silicon dioxide from the top surface of the substrate is by a chemical mechanical polishing process.

13. The MOSFET trench of claim 10 wherein the silicon substrate is an n-type epitaxial layer formed atop of an n-type substrate, and further wherein said n-type epitaxial layer has a p-type implant formed therein.

14. The MOSFET trench of claim 10 wherein the silicon dioxide fills the trench.

15. The MOSFET trench of claim 12 further wherein a nitride layer is formed prior to the HDPCVD process and the nitride layer is used as a stop layer for the chemical mechanical polishing.

16. The MOSFET trench of claim 10 further including forming a gate oxide on the sidewalls of the trench by using a thermal oxidation process.

17. The MOSFET trench of claim 10 wherein the HDPCVD process occurs at a temperature of under 300 degrees Celsius.

18. The MOSFET trench of claim 10 wherein the process of removing the silicon dioxide on the sidewalls of the trench is by an isotropic wet etch process.

19. A method for forming a thick bottom oxide for a trench MOSFET comprising:
forming an epitaxial layer atop of a semiconductor substrate, the epitaxial layer of same conductive type as the semiconductor substrate;
forming a hard mask over said epitaxial layer and patterning said hard mask to define a trench area;
forming a trench in said epitaxial layer by selectively etching said epitaxial layer and using said hard mask;
using a high density plasma chemical vapor deposition (HDPCVD) process to form silicon dioxide at least partially into the trench and on a top surface of said hard mask;
removing the silicon dioxide from the surface of the hard mask; and
removing the silicon dioxide from the sidewalls of the trench.

20. The method of claim 19 wherein the removing the silicon dioxide from the sidewalls of the trench is performed during the removing the silicon dioxide form the top surface of the hard mask.

21. The method of claim 19 wherein the removing of the silicon dioxide from the top surface of the hard mask is by a chemical mechanical polishing process.

22. The method of claim 19 wherein the substrate is n-type and said epitaxial layer is also n-type.

23. The method of claim 22 wherein an implantation process is used to form a p-layer in said n-type epitaxial layer.

24. The method of claim 19 further including forming a gate oxide on the sidewalls of the trench by using a thermal oxidation process.

25. A method for forming a thick bottom oxide for a trench MOSFET comprising:
forming an epitaxial layer atop of a semiconductor substrate, the epitaxial layer of same conductive type as the semiconductor substrate;
forming a hard mask over said epitaxial layer and patterning said hard mask to define a trench area;
forming a trench in said epitaxial layer by selectively etching said epitaxial layer and using said hard mask;
using a high density plasma chemical vapor deposition (HDPCVD) process to form silicon dioxide at least partially into the trench and on a top surface of said hard mask;
removing the silicon dioxide from the sidewalls of the trench;
forming a gate oxide on the sidewalls of the trench using thermal oxidation;
depositing a polysilicon layer until the trench is substantially filled;
performing a chemical mechanical polish until the polysilicon and silicon dioxide is removed from atop the hard mask; and
using implantation to implant the epitaxial layer until a top portion of the epitaxial layer is of opposite conductivity than the epitaxial layer.

26. The method of claim 25 wherein the substrate is n-type and said epitaxial layer is also n-type.
